(19) United States
(12) Patent Application Publication
(10) Pub. No.: US 2026/0299361 A1
(43) Pub. Date: Oct. 1, 2026

(54) Display Backplane and Display Apparatus

(71) Applicants: Hefei BOE Joint Technology Co., Ltd., Hefei, Anhui (CN); BOE Technology Group Co., Ltd., Beijing (CN)

(72) Inventors: Zhidong YUAN, Beijing (CN); Yongqian LI, Beijing (CN); Xiuting LIU, Beijing (CN)

(21) Appl. No.: 19/480,370

(22) PCT Filed: Feb. 11, 2025
(86) PCT No.: PCT/CN2025/076864

§ 371 Date: Oct. 31, 2025

(30) Foreign Application Priority Data
Mar. 4, 2024 (CN) 202410245478.4

(51) Int. Cl. G02F 1/1362; G09G 3/36

(52) U.S. Cl. CPC G02F 1/136204; G02F 1/136209; G02F 1/136286; G09G 3/3677; G09G 2330/04

(57) ABSTRACT

Please replace the Abstract with the following amended Abstract.

A display backplane and a display apparatus. The display backplane comprises: a plurality of first signal lines (1), which extend in a first direction and are sequentially arranged in a second direction, wherein the first direction intersects with the second direction; a plurality of second signal lines (2), which extend in the second direction and are sequentially arranged in the first direction, wherein each first signal line (1) is connected to at least one second signal line (2), and in a direction perpendicular to the display backplane, the second signal lines (2) and the first signal lines (1) overlap with each other; and a plurality of electrostatic protection units (601), which are electrically connected to the first signal lines (1), wherein in the direction perpendicular to the display backplane, each electrostatic protection unit (601) is located between two adjacent second signal lines (2).

### CROSS-REFERENCE TO RELATED APPLICATIONS

The present application is a U.S. National Phase Entry of International Application No. PCT/CN2025/076864 having an international filing date of Feb. 11, 2025, which claims priority to Chinese Patent Application No. 202410245478.4, filed on Mar. 4, 2024 and entitled “Display Backplane and Display Apparatus”. Contents of the above-identified applications are incorporated into the present application by reference.

### TECHNICAL FIELD

The present disclosure relates to, but is not limited to, the display technologies, and in particular to a display backplane and a display apparatus.

### BACKGROUND

An organic light emitting diode (OLED) is an active light emitting display device and has advantages such as self-luminescence, a wide viewing angle, a high contrast ratio, low power consumption, an extremely high response speed. With continuous development of display technologies, a display apparatus in which an OLED is used as a light emitting element and signal control is performed by a thin film transistor (TFT) has become a mainstream product in the field of display at present.

However, there is static electricity in the preparation process of the display backplane, which is not conducive to the yield of the display backplane.

### SUMMARY

The following is a summary of subject matters described herein in detail. This summary is not intended to limit the protection scope of claims.

In a first aspect, an embodiment of the present disclosure provides a display backplane, including a plurality of first signal lines, a plurality of second signal lines, and a plurality of electrostatic prevention units. The plurality of first signal lines extend in a first direction, and are arranged sequentially in a second direction, and the first direction intersects with the second direction. The plurality of second signal lines extend in the second direction, and are arranged sequentially in the first direction. A first signal line of plurality of the first signal lines is connected to at least one second signal line of the second signal lines, and the second signal line and the first signal line overlap with each other in a direction perpendicular to the display backplane. An electrostatic prevention unit of the plurality of electrostatic prevention units is electrically connected to the first signal line. In the direction perpendicular to the display backplane, the electrostatic prevention unit is positioned between two adjacent second signal lines, and the electrostatic prevention unit overlaps with the two adjacent second signal lines, respectively.

In an exemplary implementation, the display backplane includes a display region and a bezel region around the display region. The bezel region includes a bonding region located on a side of the display region along the second direction. The bezel region includes a gate drive circuit, and the bonding region includes a plurality of bonding pins. The second signal line is connected to the gate drive circuit, one end of the first signal line is connected to at least one of the second signal lines, and the other end of the first signal line is connected to a bonding pin of the plurality of bonding pins.

In an exemplary implementation, a minimum overlapping dimension between the electrostatic prevention unit and the second signal line is greater than or equal to 0.9 microns.

In an exemplary implementation, overlapping areas between the electrostatic prevention unit and different second signal lines are equal.

In an exemplary implementation, a single electrostatic prevention unit overlaps with a single first signal line, and overlapping areas between different electrostatic prevention units and the first signal lines are equal.

In an exemplary implementation, an orthographic projection of the electrostatic prevention unit on the display backplane is axisymmetric, and an axis of symmetry of the electrostatic prevention unit extends along the second direction.

In an exemplary implementation, a material of the electrostatic prevention unit is a semiconductor material.

In an exemplary implementation, the display backplane includes a substrate and a first semiconductor layer, a first metal layer, and a second metal layer that are provided sequentially on the substrate. The electrostatic prevention unit is located in the first semiconductor layer, the second signal line is located in the first metal layer, and the first signal line is located in the second metal layer. A single electrostatic prevention unit is provided between two adjacent second signal lines, and the electrostatic prevention unit is in a shape of a trace. In a direction perpendicular to the substrate, two ends of the electrostatic prevention unit overlap with the two adjacent second signal lines, respectively.

In an exemplary implementation, a third insulating layer is provided between the first metal layer and the second metal layer. The third insulating layer includes a first via through which the first signal line is electrically connected to the electrostatic prevention unit.

In an exemplary implementation, the first via exposes a surface of the electrostatic prevention unit, and the first signal line is in contact with the electrostatic prevention unit through the first via.

In an exemplary implementation, the first metal layer includes a first connection portion, and an orthographic projection of the first connection portion on the substrate and an orthographic projection of the electrostatic prevention unit on the substrate overlap with each other. The first via exposes a surface of the first connection portion, and the first signal line is in contact with the first connection portion through the first via.

In an exemplary implementation, the display backplane includes a substrate, and a second shading layer, a second semiconductor layer, and a third metal layer that are provided sequentially on the substrate. The first signal line is located in the second shading layer, the electrostatic prevention unit is located in the second semiconductor layer, and the second signal line is located in the third metal layer.

In an exemplary implementation, the third metal layer further includes a second connection portion, and the second connection portion is in contact with the electrostatic prevention unit and the first signal line, respectively.

In an exemplary implementation, an orthographic projection of the second connection portion on the substrate and an orthographic projection of the electrostatic prevention unit on the substrate overlap with each other.

In a second aspect, an embodiment of the present disclosure provides a display apparatus including the display backplane described above.

Other aspects of the present disclosure may be comprehended after the drawings and the detailed descriptions are read and understood.

### BRIEF DESCRIPTION OF DRAWINGS

Accompanying drawings are used to provide an understanding of technical solutions of the present disclosure, and form a part of the specification. The accompanying drawings and embodiments of the present disclosure are adopted to explain the technical solutions of the present disclosure, and do not form limitations on the technical solutions of the present disclosure.

FIG. 1 is a schematic diagram of a planar structure of a display backplane;

FIG. 2 is an enlarged schematic diagram of a dashed region C of FIG. 1 in an exemplary embodiment;

FIG. 3 is an enlarged schematic diagram of a dashed area E of FIG. 2 in an exemplary embodiment;

FIG. 4 is a cross-sectional view taken along a direction AA in FIG. 2 in an exemplary implementation;

FIG. 5 is an enlarged schematic diagram of a dashed region C of FIG. 1 in another exemplary embodiment;

FIG. 6 is a cross-sectional view taken along a direction BB in FIG. 5 in an exemplary embodiment;

FIG. 7 is an enlarged schematic diagram of a dashed region C of FIG. 1 in yet another exemplary embodiment;

FIG. 8 is a cross-sectional view taken along a direction FF in FIG. 7 in an exemplary embodiment; and

FIG. 9 is an enlarged schematic diagram of a dashed region C of FIG. 1 in yet another exemplary embodiment.

### DETAILED DESCRIPTION

Multiple embodiments are described in the present disclosure. However, the description is exemplary and unrestrictive. Moreover, it is apparent to those of ordinary skills in the art that there may be more embodiments and implementation solutions in the scope of the embodiments described in the present disclosure. Although many possible combinations of features are shown in the accompanying drawings and discussed in specific implementations, many other combinations of the disclosed features are also possible. Unless expressly limited, any feature or element of any embodiment may be used in combination with, or may replace, any other feature or element in any other embodiment.

The present disclosure includes and conceives combinations with the features and elements known to those of ordinary skills in the art. The embodiments, features, and elements that have been disclosed in the present disclosure may also be combined with any conventional feature or element to form unique inventive solutions defined by the claims. Any feature or element of any embodiment may also be combined with a feature or an element from another inventive solution to form another unique inventive solution defined by the claims. Therefore, it should be understood that any of the features shown and/or discussed in the present disclosure may be implemented alone or in any suitable combination. Therefore, the embodiments are not limited except the limitations by the appended claims and equivalents thereof. Furthermore, various modifications and variations may be made within the protection scope of the appended claims.

Moreover, when describing representative embodiments, the specification may have presented a method and/or a process as a particular sequence of acts. However, to an extent that the method or the process does not depend on the specific sequence of the acts described herein, the method or the process should not be limited to the acts with the specific sequence. Those of ordinary skills in the art will understand that other sequences of acts are also possible. Therefore, the specific sequence of the acts illustrated in the specification should not be interpreted as a limitation on claims. Moreover, claims directed to the method and/or process should not be limited to performing their acts in a described sequence, and those skilled in the art may readily understand that these sequences may be varied and still remain within the essence and scope of the embodiments of the present disclosure.

In the drawings, a size of one or more constituent elements, a thickness of a layer, or a region is sometimes exaggerated for clarity. In addition, the accompanying drawings schematically illustrate ideal examples, and an implementation of the present disclosure is not limited to shapes, numerical values, or the like shown in the drawings.

Ordinal numerals “first”, “second”, “third” and the like in the specification are set not to form limits in numbers but only to avoid confusion between constituent elements. In the present disclosure, “a plurality of” represents two or more than two.

In the specification, for convenience, expressions “central”, “above”, “below”, “front”, “back”, “vertical”, “horizontal”, “top”, “bottom”, “inside”, “outside” and the like for indicating directional or positional relationships are used to illustrate positional relationships between the constituent elements with reference to the accompanying drawings, not to indicate or imply that involved devices or elements are required to have specific orientations or are structured and operated in the specific orientations but only to easily describe the present specification and simplify the description, and thus should not be understood as limitations on the present disclosure. The positional relationships between the constituent elements are changed as appropriate according to directions of the constituent elements described. Therefore, appropriate replacements based on situations are allowed, which is not limited to the expressions in the specification.

In the specification, unless otherwise explicitly specified and defined, terms “mounting”, “coupling”, and “connection” should be understood in a broad sense. For example, a connection may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand meanings of the aforementioned terms in the present disclosure according to situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as a “source terminal” and a “drain terminal”, are interchangeable in the specification.

In the specification, an “electrical connection” includes a case that constituent elements are connected together through an element with a certain electrical action. The “element with a certain electrical action” is not particularly limited as long as electrical signals between the connected constituent elements can be transmitted. Examples of the “element with a certain electrical action” not only include an electrode and a wiring, but also include a switching element such as a transistor, a resistor, an inductor, a capacitor, other elements with various functions, etc.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

The embodiments of the present disclosure will be described below with reference to the drawings in detail.

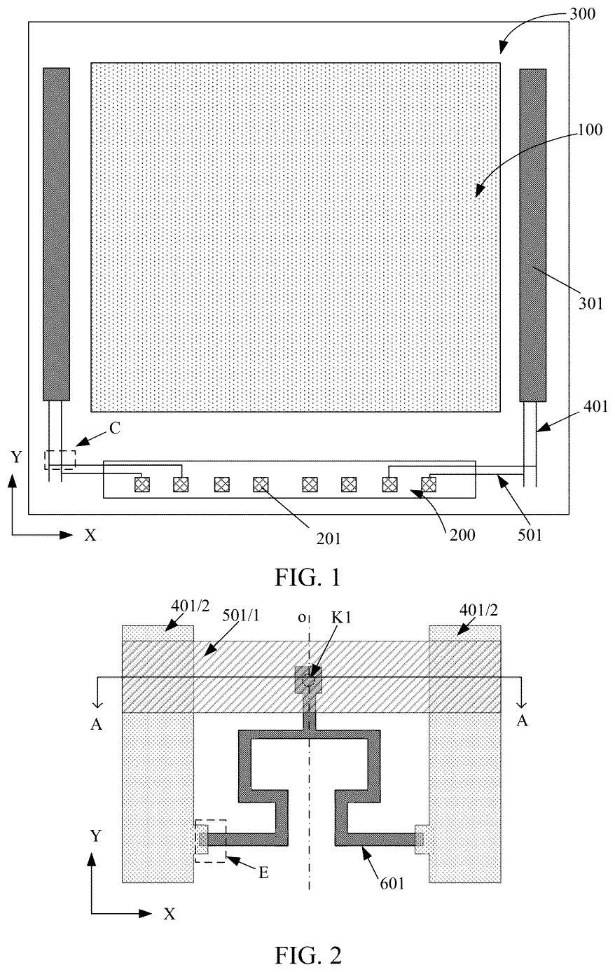

FIG. 1 is a schematic diagram of a planar structure of a display backplane. As shown in FIG. 1, in an exemplary implementation, the display backplane includes a display region 100 and a bezel region 300 provided around the display region 100, and the bezel region 300 may include a bonding region 200 located on a side of the display region 100 along a second direction Y. The display region 100 includes at least a plurality of pixel units regularly arranged, for example, the plurality of pixel units may be arranged in an array along a first direction X and a second direction Y, and the first direction X intersects with the second direction Y. The plurality of pixel units are configured to display a dynamic picture or a static image, and the display region 100 may be referred to as an active area (AA). In an exemplary implementation, the display substrate may be deformable, e.g., may be crimped, bent, folded, or curled.

In an exemplary implementation, a shape of the display region 100 may be a quadrangle, a circle, an ellipse, a polygon of other shapes, an irregular shape, or the like, and a shape of a corner portion of the display region 100 may be rounded, which is not limited in this disclosure.

In an exemplary implementation mode, the bonding region 200 may include a fan-out region, a drive chip region, and a bonding pin region that are provided sequentially along a direction away from the display region 100. The fan-out region is connected to the display region 100 and may at least include a plurality of data lead-out lines parallel to each other. The drive chip region may at least include an Integrated Circuit (IC) and is configured to be connected to a plurality of data fan-out lines. The bonding pin region may at least include a plurality of bonding pads, and is configured to be bonded to and connected to an external Flexible Printed Circuit (FPC).

In an exemplary implementation, the bonding region 200 may further include a bending region, and the bending region may be located between the fan-out region and the drive chip region. The bending region may be connected to the fan-out region, may include a composite insulating layer provided with a groove, and may be configured to bend the bonding region 200 to a back surface of the display region 100.

In an exemplary implementation, the bezel region 300 may include a circuit region, which may be provided on two sides of the display region 100 along the first direction X and may be connected to the display region 100. The circuit region may include at least a gate drive circuit 301 connected to a scanning signal line and a light emitting signal line of a pixel drive circuit in the display region 100.

In an exemplary implementation, the display backplane may include a plurality of gate lines 401 extending in the second direction Y and a gate connection line (Propel Link Gate, PLG) 501 extending in the first direction X. The gate lines 401 may be connected to the gate drive circuit 301, and the gate connection line 501 may connect the gate lines 401 to a bonding pin 201 of the integrated circuit to transmit signals from the integrated circuit to the gate drive circuit 301. In an exemplary implementation, the gate connection line 501 may be connected to the pin 201 of the integrated circuit via the fan-out region. In an exemplary implementation, the gate connection line 501 may connect the gate line 401 to the corresponding bonding pad, which is not limited in this disclosure.

Through research, it is found that in the preparation process of the display backplane, static electricity is easily generated in the processes of transporting, dry etching and cleaning the display backplane. When the signal lines in adjacent film layers overlap, the signal lines at the overlapping regions are susceptible to electrostatic damage, which affects the yield of the display backplane. As shown in FIG. 1, in a direction perpendicular to the display backplane, since the plurality of gate connection lines 501 overlap with the plurality of gate lines 401, when static electricity cannot be discharged in time, there is a greater risk of electrostatic damage here, which will greatly affect the yield of the display backplane.

An embodiment of the present disclosure provides a display backplane, including a plurality of first signal lines, a plurality of second signal lines, and a plurality of electrostatic prevention units. The plurality of first signal lines extend in a first direction, and are arranged sequentially in a second direction, and the first direction intersects with the second direction. The plurality of second signal lines extend in the second direction, and are arranged sequentially in the first direction. The first signal line is connected to at least one of the second signal lines, and the second signal line and the first signal line overlap with each other in a direction perpendicular to the display backplane. The electrostatic prevention unit is electrically connected to the first signal line. In the direction perpendicular to the display backplane, the electrostatic prevention unit is positioned between two adjacent second signal lines, and the electrostatic prevention unit overlaps with the two adjacent second signal lines, respectively.

In the display backplane provided by the embodiment of the present disclosure, when the first signal line and the second signal line overlap with each other, the electrostatic prevention unit is provided between the two adjacent second signal lines, the electrostatic prevention unit respectively overlaps with two adjacent second signal lines, and the electrostatic prevention unit is electrically connected with the first signal line. In this way, when there is static electricity on the first signal line, the static electricity can be introduced into the electrostatic prevention unit along the first signal line, and when there is static electricity on the second signal line, the static electricity can be introduced into the electrostatic prevention unit from an overlapping portion between the second signal line and the electrostatic prevention unit. As a result, the static electricity is discharged in time, preventing electrostatic damage to the signal lines, and helping to improve the yield of the display backplane.

In an exemplary implementation, the display backplane includes a display region and a bezel region around the display region. The bezel region includes a bonding region located on a side of the display region along the second direction. The bezel region includes a gate drive circuit, and the bonding region includes a plurality of bonding pins. The second signal line is connected to the gate drive circuit, one end of the first signal line is connected to at least one of the second signal lines, and the other end of the first signal line is connected to the bonding pin.

In an exemplary implementation, a minimum overlapping dimension between the electrostatic prevention unit and the second signal line is greater than or equal to 0.9 microns.

In an exemplary implementation, overlapping areas between the electrostatic prevention unit and different second signal lines are equal.

In an exemplary implementation, a single electrostatic prevention unit overlaps with a single first signal line, and overlapping areas between different electrostatic prevention units and the first signal lines are equal.

In an exemplary implementation, an orthographic projection of the electrostatic prevention unit on the display backplane is axisymmetric, and an axis of symmetry of the electrostatic prevention unit extends along the second direction.

In the following embodiment, the display backplane provided by the embodiment of the present disclosure will be described by taking the first signal line 1 as the gate connection line 501 and the second signal line 2 as the gate line 401 as an example. The reference signs of the first signal line 1 and the second signal line 2 are only marked in FIG. 2, and are omitted in other figures. The electrostatic prevention unit mentioned in the embodiment of the present disclosure may be applied not only between the gate connection line 501 and the gate line 401, but also to other cases where the traces overlap, which is not limited in this disclosure.

FIG. 2 is an enlarged schematic diagram of a dashed region C of FIG. 1 in an exemplary embodiment. As shown in FIG. 2, two adjacent gate lines 401 extend in the second direction Y, and the two gate lines 401 overlap with the gate connection line 501 extending in the first direction X. An electrostatic prevention unit 601 is provided on the display backplane, and the electrostatic prevention unit 601 is electrically connected with the gate connection line 501. The electrostatic prevention unit 601 is located between the two adjacent gate lines 401 in a direction perpendicular to the display backplane, and an orthographic projection of the electrostatic prevention unit 601 overlaps with orthographic projections of the two adjacent gate lines 401, respectively. When there is static electricity on the gate connection line 501, the static electricity can be introduced into the electrostatic prevention unit 601 along the gate connection line 501. When there is static electricity on the gate line 401, the static electricity can be introduced into the electrostatic prevention unit 601 from the overlapping portion between the gate line 401 and the electrostatic prevention unit 601, thereby discharging the static electricity in time, preventing electrostatic damage to the signal line, and helping to improve the yield of the display backplane. FIG. 2 illustrates an overlap between two adjacent gate lines 401 and one gate connection line 501, and a single electrostatic prevention unit 601 is provided between the two adjacent gate lines 401. In other implementations, a plurality of gate lines 401 and a plurality of gate connection lines 501 may overlap with each other, and a plurality of electrostatic prevention units 601 may be provided, which is not limited in this disclosure.

In an exemplary implementation, the gate connection line 501 may be connected to the electrostatic prevention unit 601 through a first via K1, which is not limited in this disclosure.

In an exemplary implementation, the electrostatic prevention unit 601 may have an axis of symmetry o extending along the second direction Y, the electrostatic prevention unit 601 may be axisymmetric along the axis of symmetry o, and the electrostatic prevention unit 601 and the gate line 401 overlapping with the electrostatic prevention unit 601 may be axisymmetric along the axis of symmetry o, which is not limited in this disclosure.

FIG. 3 is an enlarged schematic diagram of a dashed region E of FIG. 2 in an exemplary embodiment. As shown in FIG. 3, a minimum overlapping dimension between the electrostatic prevention unit 601 and the gate line 401 may be a first overlapping dimension d, and the first overlapping dimension d may be a dimension along the first direction X. The first overlapping dimension d may be set to greater than or equal to 0.9 micron, for example, may be set to greater than or equal to 1 micron, which is not limited in the present disclosure. By setting the minimum value of the first overlapping dimension d, the overlapping area between the electrostatic prevention unit 601 and the gate line 401 can be ensured, thus ensuring smooth electrostatic discharge.

In an exemplary implementation, the electrostatic prevention unit 601 may overlap with the plurality of gate lines 401, and overlapping areas between the electrostatic prevention unit 601 and each gate line 401 may be set to be equal. By setting the overlapping areas between the electrostatic prevention unit 601 and each gate line 401 to be equal, it is possible to ensure that the electrostatic discharge conditions of each gate line 401 are the same, which is beneficial to stable electrostatic discharge. When the overlapping areas between the electrostatic prevention unit 601 and the gate lines 401 are not equal, static electricity is easily to concentrate and move to the electrostatic prevention unit 601 having a small lapping area, thus affecting the electrostatic discharge effect.

In an exemplary implementation, the display backplane may include a plurality of gate connection lines 501, and the plurality of gate connection lines 501 may be arranged sequentially along the second direction Y. The overlapping areas between different gate connection lines 501 and the corresponding electrostatic prevention unit 601 may be equal, which helps to ensure that the entire display backplane has a uniform electrostatic discharge effect.

In an exemplary implementation, a material of the electrostatic prevention unit 601 may be a semiconductor material, such as non-conductive Indium Gallium Zinc Oxide (IGZO), and the electrostatic prevention unit 601 may be provided in the same layer as an active layer of a transistor in the display backplane, which helps to save preparation steps and production costs. In the present disclosure, “A and B are provided in the same layer” means that A and B are simultaneously formed by a same patterning process when preparing the display backplane. In other embodiments, other materials with high impedance characteristics, such as low-temperature polysilicon, etc., may be selected, and the present disclosure is not limited thereto.

In an exemplary implementation, the electrostatic discharge effect of the electrostatic prevention unit 601 depends on its own impedance, and the resistance value of the electrostatic prevention unit 601 may be set according to the normal operating voltage of the gate line 401 and the gate connection line 501. In an exemplary implementation, the normal operating voltage of the gate line 401 may be a first voltage, and the normal operating voltage of the gate connection line 501 may be a second voltage. When the difference between the first voltage and the second voltage is 10 volts, the resistance value of the electrostatic prevention unit 601 may be set to be greater than or equal to 45KΩ and less than or equal to 55KΩ, for example, the resistance value of the electrostatic prevention unit 601 may be about 50KΩ. The smaller the difference between the first voltage and the second voltage is, the smaller the resistance value of the electrostatic prevention unit 601 may be. The larger the resistance value of the electrostatic prevention unit 601 is, the larger the electrostatic current it can withstand, but the slower the electrostatic discharge rate. Therefore, the resistance value of the electrostatic prevention unit 601 can be set according to the actual demand in order to obtain a better electrostatic discharge effect, and the present disclosure is not limited thereto.

In the exemplary embodiment, since the resistance value of the electrostatic prevention unit 601 is related to its own length and diameter and the like, after determining the resistance value of the electrostatic prevention unit 601, dimension parameters such as the length and diameter of the electrostatic prevention unit 601 may be set as needed. For example, when the distance between adjacent gate lines 401 is relatively small, the diameter of the electrostatic prevention unit 601 may be set to be smaller and the length of the electrostatic prevention unit 601 may be set to be longer, so as to facilitate trace arrangement. In the accompanying drawings, a single electrostatic prevention unit 601 is presented in the shape of the trace. In practical applications, the shape of the electrostatic prevention unit 601 can be set as needed, such as shapes of straight line, zigzag line, arc line, wavy line, “S”, irregular line, and the like, and can also be set as triangular, circular, elliptical, quadrilateral, polygonal and irregular shapes, and the like. The present disclosure is not limited thereto.

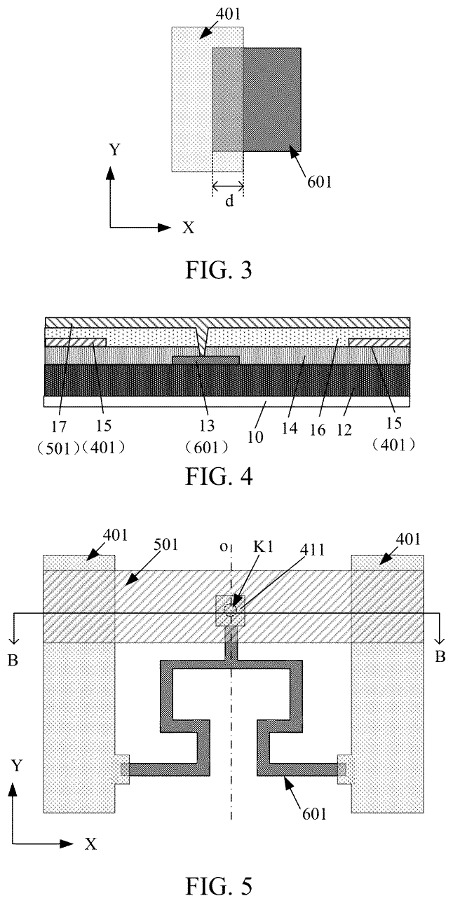

FIG. 4 is a cross-sectional view taken along a direction AA in FIG. 2 in an exemplary embodiment, illustrating the structure of the display backplane at the gate line and the gate connection line, and omitting the remaining structures of the display backplane. As shown in FIG. 4, in a direction perpendicular to the display backplane, the display backplane may include a substrate 10, a first insulating layer 12, a first semiconductor layer 13, a second insulating layer 14, a first metal layer 15, a third insulating layer 16, and a second metal layer 17 that are provided sequentially. The electrostatic prevention unit 601 may be located in the first semiconductor layer 13, the gate line 401 may be located in the first metal layer 15, and the gate connection line 501 may be located in the second metal layer 17. In an exemplary implementation, an active layer of the transistor in the display backplane may be located in the first semiconductor layer 13, a gate of the transistor may be located in the first metal layer 15, and the first metal layer 15 may be referred to as a gate layer. The first electrode and the second electrode of the transistor may be located in the second metal layer 17, and the second metal layer 17 may be referred to as a source-drain metal layer. The second insulating layer 14 may be referred to as a gate insulating layer. Since the gate insulating layer has a small thickness, when there is static electricity, the static electricity can enter the electrostatic prevention unit 601 located in the first semiconductor layer 13 from the gate line 401 located in the first metal layer 15 after passing through the second insulating layer 14. Thus, the gate line 401 may not be connected directly to the electrostatic prevention unit 601, and the electrostatic discharge effect may not be affected. The first insulating layer 12 may be referred to as a buffer layer, and the third insulating layer 16 may be referred to as an interlayer insulating layer. A shading layer can be provided between the substrate 10 and the first insulating layer 12, which is not limited in this disclosure.

FIG. 5 is an enlarged schematic diagram of a dashed region C of FIG. 1 in yet another exemplary embodiment. FIG. 5 is different from FIG. 2 in that a first connection portion 411 is added. An orthographic projection of the first connection portion 411 on the substrate may overlap with an orthographic projection of the electrostatic prevention unit 601 on the substrate, and a gate connection line 501 may be connected to the first connection portion 411 through the first via K1. As shown in FIG. 5, the first connection portion 411 may be provided in the same layer as the gate line 401. After moving to the first connection portion 411, static electricity in the gate connection line 501 may pass through the second insulating layer 14 and enter the electrostatic prevention unit 601. By providing the first connection portion 411, the first via K1 originally directly formed on the surface of the electrostatic prevention unit 601 can be only formed on the first connection portion 411. The first connection portion 411 can discharge static electricity from the electrostatic prevention unit 601 through the second insulating layer 14, the flexibility of trace arrangement can be improved, and the difficulty and accuracy of drilling can be reduced. The first connection portion 411 can be made of the same material as the gate line 401 without increasing the production process.

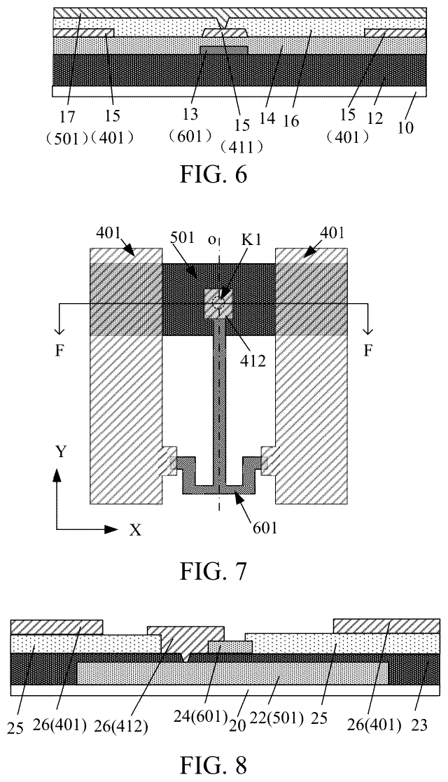

FIG. 6 is a cross-sectional view taken along a direction BB in FIG. 5 in an exemplary embodiment, illustrating the structure of the display backplane at the gate line and the gate connection line, and omitting the remaining structures of the display backplane. FIG. 6 is different from FIG. 4 in that the first metal layer 15 includes a first connection portion 411, and the gate connection line 501 is connected to the first connection portion 411. The remaining structures may be described with reference to FIG. 4, and will not be repeated herein.

FIG. 7 is an enlarged schematic view of a dashed region C of FIG. 1 in another exemplary embodiment. FIG. 7 is different from FIG. 2 in that a second connection portion 412 is added, and the shape of the electrostatic prevention unit 601 and the positioning of the film layers are altered. FIG. 8 is a cross-sectional view taken along a direction FF in FIG. 7 in an exemplary embodiment, illustrating the structure of the display backplane at the gate line and the gate connection line, and omitting the remaining structures of the display backplane. As shown in FIG. 8, the display backplane may include a substrate 20, a second shading layer 22, a fifth insulating layer 23, a second semiconductor layer 24, a sixth insulating layer 25, and a third metal layer 26 provided sequentially in a direction perpendicular to the display backplane. The display backplane provided in this embodiment has two metal layers, that are a second shading layer 22 and a third metal layer 26, can be prepared by using five masks, and can be used in an array substrate of liquid crystal display. The electrostatic prevention unit 601 may be located in the second semiconductor layer 24, the gate line 401 and the second connection portion 412 may be located in the third metal layer 26, and the gate connection line 501 may be located in the second shading layer 22. In an exemplary implementation, the active layer of the transistor in the display backplane may be located in the second semiconductor layer 24. The gate, first electrode, and second electrode of the transistor may be located in the third metal layer 26. A first conductive layer 21 may use a transparent conductive material. The fifth insulating layer 23 may be referred to as a buffer layer. The sixth insulating layer 25 may be referred to as a gate insulating layer. The first conductive layer may be provided between the substrate 20 and the second shading layer 22 as required, which is not limited in this disclosure.

As shown in FIGS. 7 and 8, an orthographic projection of the second connection portion 412 on the substrate and an orthographic projection of the electrostatic prevention unit 601 on the substrate may overlap with each other, and the second connection portion 412 and the electrostatic prevention unit 601 are in contact with each other. The gate connection line 501 may be connected to the second connection portion 412 through the first via K1, thereby realizing electrical connection between the gate connection line 501 and the electrostatic prevention unit 601.

As shown in FIG. 7, in a case where the distance between two adjacent gate lines 401 is relatively small, the shape of the electrostatic prevention unit 601 can be controlled, and a body portion of the electrostatic prevention unit 601 can extend in the second direction Y. By providing an extension portion extending in the first direction X that overlaps with the gate lines 401, a smaller space may be occupied, which facilitates wiring on the display backplane.

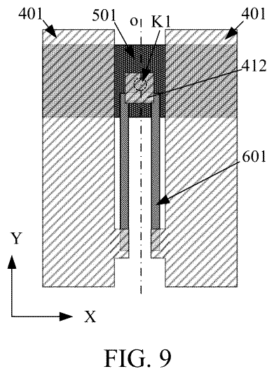

FIG. 9 is an enlarged schematic view of a dashed region C of FIG. 1 in another exemplary embodiment. FIG. 9 is different from FIG. 7 in that the electrostatic prevention unit 601 has a different shape. The cross-sectional structure of FIG. 9 at the same position can refer to FIG. 8, and the remaining structures can refer to the description of FIGS. 7 and 8, and will not be repeated here. As shown in FIG. 9, when the distance between the two adjacent gate lines 401 is relatively small, the electrostatic prevention unit 601 may be in an “n” shape, both ends of the “n” shape may overlap with the gate lines 401, and the top end of the “n” shape may overlap with the second connection portion 412, thereby occupying a smaller space.

An embodiment of the present disclosure also provides a display apparatus, which includes the display backplane of any one of the aforementioned embodiments. The display apparatus may be any product or component with a display function such as an OLED display, a LED display, a LCD display, a mobile phone, a tablet, a television, a display, a laptop, a digital photo frame, and a navigator, which is not limited in the embodiments of the present disclosure.

Although the embodiments disclosed in the present disclosure are described as above, the described contents are only embodiments which are adopted in order to facilitate understanding of the present disclosure, and are not intended to limit the present disclosure. Any skilled person in the art to which the present disclosure pertains can make any modifications and alterations in forms and details of implementation without departing from the spirit and scope of the present disclosure. However, the patent protection scope of the present disclosure should be subject to the scope defined by the appended claims.

1. A display backplane, comprising:
a plurality of first signal lines extending in a first direction, wherein the plurality of first signal lines are arranged sequentially in a second direction, and the first direction intersects with the second direction;
a plurality of second signal lines extending in the second direction, wherein the plurality of second signal lines are arranged sequentially in the first direction, a first signal line of the plurality of first signal lines is connected to at least one second signal line of the plurality of second signal lines, and the second signal line and the first signal line overlap with each other in a direction perpendicular to the display backplane; and
a plurality of electrostatic prevention units, wherein an electrostatic prevention unit of the plurality of electrostatic prevention units is electrically connected to the first signal line; in the direction perpendicular to the display backplane, the electrostatic prevention unit is positioned between two adjacent second signal lines, and the electrostatic prevention unit overlaps with the two adjacent second signal lines, respectively.

2. The display backplane according to claim 1, wherein the display backplane comprises a display region and a bezel region around the display region, the bezel region comprises a bonding region located on a side of the display region along the second direction, the bezel region comprises a gate drive circuit, and the bonding region comprises a plurality of bonding pins; and
the second signal line is connected to the gate drive circuit, one end of the first signal line is connected to at least one of the plurality of second signal lines, and the other end of the first signal line is connected to a bonding pin of the plurality of bonding pins.

3. The display backplane according to claim 1, wherein a minimum overlapping dimension between the electrostatic prevention unit and the second signal line is greater than or equal to 0.9 microns.

4. The display backplane according to claim 3, wherein overlapping areas between the electrostatic prevention unit and different second signal lines are equal.

5. The display backplane according to claim 1, wherein a single electrostatic prevention unit overlaps with a single first signal line, and overlapping areas between different electrostatic prevention units and the first signal lines are equal.

6. The display backplane according to claim 1, wherein an orthographic projection of the electrostatic prevention unit on the display backplane is axisymmetric, and an axis of symmetry of the electrostatic prevention unit extends along the second direction.

7. The display backplane according to claim 1, wherein a material of the electrostatic prevention unit is a semiconductor material.

8. The display backplane according to claim 1, wherein the display backplane comprises a substrate and a first semiconductor layer, a first metal layer, and a second metal layer that are provided sequentially on the substrate, the electrostatic prevention unit is located in the first semiconductor layer, the second signal line is located in the first metal layer, and the first signal line is located in the second metal layer; and
a single electrostatic prevention unit is provided between the two adjacent second signal lines, and the electrostatic prevention unit is in a shape of a trace; in a direction perpendicular to the substrate, two ends of the electrostatic prevention unit overlap with the two adjacent second signal lines, respectively.

9. The display backplane according to claim 8, wherein a third insulating layer is provided between the first metal layer and the second metal layer, the third insulating layer comprises a first via through which the first signal line is electrically connected to the electrostatic prevention unit.

10. The display backplane according to claim 9, wherein the first via exposes a surface of the electrostatic prevention unit, and the first signal line is in contact with the electrostatic prevention unit through the first via.

11. The display backplane according to claim 9, wherein the first metal layer comprises a first connection portion, an orthographic projection of the first connection portion on the substrate and an orthographic projection of the electrostatic prevention unit on the substrate overlap with each other, the first via exposes a surface of the first connection portion, and the first signal line is in contact with the first connection portion through the first via.

12. The display backplane according to claim 1, wherein the display backplane comprises a substrate, and a second shading layer, a second semiconductor layer, and a third metal layer that are provided sequentially on the substrate, the first signal line is located in the second shading layer, the electrostatic prevention unit is located in the second semiconductor layer, and the second signal line is located in the third metal layer.

13. The display backplane according to claim 12, wherein the third metal layer further comprises a second connection portion, and the second connection portion is in contact with the electrostatic prevention unit and the first signal line, respectively.

14. The display backplane according to claim 13, wherein an orthographic projection of the second connection portion on the substrate and an orthographic projection of the electrostatic prevention unit on the substrate overlap with each other.

15. A display apparatus, comprising the display backplane according to claim 1.

16. The display backplane according to claim 1, wherein the first signal line, the second signal line and the electrostatic prevention unit are provided on a substrate of the display backplane; in a direction perpendicular to the substrate, the electrostatic prevention unit is located on a side of the first signal line and the second signal line close to the substrate.

17. The display backplane according to claim 16, wherein in the direction perpendicular to the substrate, the electrostatic prevention unit is located on a side of the first signal line close to the substrate; the first signal line is located on a side of the second signal line close to the substrate.

18. The display backplane according to claim 11, wherein the first signal line is electrically connected with the electrostatic prevention unit through the first connection portion.

19. The display backplane according to claim 1, wherein the first signal line, the second signal line and the electrostatic prevention unit are provided on a substrate of the display backplane; in a direction perpendicular to the substrate, the electrostatic prevention unit is located between the first signal line and the second signal line.

20. The display backplane according to claim 13, wherein the electrostatic prevention unit is electrically connected with the first signal line through the second connection portion.
